(19) United States
(12) Patent Application Publication
(10) Pub. No.: US 2009/0160002 A1
(43) Pub. Date: Jun. 25, 2009

(54) IMAGE SENSOR AND METHOD FOR FABRICATING THE SAME

(76) Inventor: Young-Je Yun, Ansan-si (KR)

Correspondence Address: SHERR & VAUGHN, PLLC, 620 HERNDON PARKWAY, SUITE 200, HERNDON, VA, 20170, US

(21) Appl. No.: 12/233,652

(22) Filed: Sep. 19, 2008

(30) Foreign Application Priority Data
Dec. 24, 2007 (KR) 10-2007-0136571

(51) Int. Cl. H01L 31/0232; H01L 31/18

(52) U.S. Cl. 257/432; 438/70; 257/E31.127

(57) ABSTRACT

An image sensor may include an image sensor may include a photodiode formed over a semiconductor substrate. An interlayer dielectric, which may include a plurality of metal wires in a transistor region, may be formed over the semiconductor substrate, including a waveguide dielectric for guiding incident light in a photodiode region. A refractive layer may be formed at a bottom of the waveguide dielectric in the interlayer dielectric. A color filter may be formed over an upper surface of the interlayer dielectric. An overcoat may be formed over the color filter. A micro lens may be formed over the interlayer dielectric. Accordingly, high reflectivity at a bottom of the wave guide can be effectively restrained while guaranteeing reflectivity of the wave guide with respect light which is not vertically incident.

The present application claims priority under 35 U.S.C. 119 to Korean Patent Application No. 10-2007-0136571 (filed on Dec. 24, 2007), which is hereby incorporated by reference in its entirety.

### BACKGROUND

An image sensor may be a semiconductor device that converts an optical image to an electric signal. Semiconductor image sensors can be classified into charge coupled devices (CCD) and complementary metal-oxide semiconductor (CMOS) image sensors. CMOS image sensors use a switching method with at least one MOS transistor per pixel, while simultaneously integrating a control circuit and a signal processing circuit. The CMOS sensor detects the output through the MOS transistor.

A CMOS image sensor may include a photo diode and a plurality of the MOS transistors. Basically, a CMOS image sensor performs imaging by converting a light signal, that is, a visible ray incident from the front or back of an image sensor chip, to an electric signal. Recently, a vertical image sensor having a vertical photodiode has been developed. In contrast to a horizontal image sensor, the vertical image sensor is capable of implementing a variety of colors in one pixel.

FIG. 1 is a sectional view of a related CMOS image sensor which is fabricated by the following processes. Referring to FIG. 1, at least one photodiode 2 may be formed over a semiconductor substrate 1. Over the semiconductor substrate 1 including the photodiode 2, an interlayer dielectric 3 of a multi-layered structure including metal wires may be formed. A protection dielectric 4 may be formed by depositing an oxide or a nitride over the interlayer dielectric 3 using a vapor deposition technique. Additionally, at least one color filter may be formed over the protection dielectric 4 corresponding to the photodiode 2. Finally, at least one micro lens 7 may be formed. An overcoat may be added to a lower part of the micro lens 7.

Among the above fabrication processes for the image sensor, main processes include forming the micro lens 7 for focusing light, forming the color filters for discriminating different color signals of the light (e.g., red, green and blue), and forming the photodiode 2. The photodiode 2 generates electric signals by collecting electrons generated from the focused light.

The interlayer dielectric 3 of the above image sensor is thicker than an interlayer dielectric of the CCD. Due to this difference, as the pixel pitch is reduced, deterioration of proper focusing of the photodiode 2 occurs more seriously in the CMOS image sensor than in the CCD, even when an optimal micro lens 7 is used with the CMOS image sensor. This is because, under the optimal conditions with micro lens 7, a minimum spot size enabling focusing of light is proportional to a focal distance, and related to a numerical aperture. In a pixel of the image sensor, the numerical aperture corresponds to the pixel pitch and the focal distance corresponds to the thickness of the interlayer dielectric 3 including the metal wires therein. Therefore, the size of the pixel and the thickness of the interlayer dielectric 3 need to be reduced in order to obtain a better focus.

However, in the related CMOS image sensor, reduction of the thickness of the interlayer dielectric 3 is limited. That is, there is a limit on pixel pitch allowing no more reduction of the pixel size. For example, the limit on pixel pitch is estimated as about 1.75 μm. In order to overcome the related limit, an inorganic micro lens may be formed inside the interlayer dielectric 3. However, this introduces great complexity into the fabrication process.

Alternatively, a wave guide which provides a transmission path for incident light may be further included as shown in FIGS. 2A and 2B in order to overcome the limit. FIG. 2A is a sectional view showing a related image sensor equipped with a wave guide. FIG. 2B shows the incident light in the image sensor of FIG. 2A. As shown in FIG. 2A, a trench having almost the same size as the pixel is formed on an upper part of the photodiode 2 with a depth almost corresponding to the thickness of the interlayer dielectric 3.

A wave guide 8 is formed by completely filling the trench with a spin on glass (SOG) or a material having a greater refraction coefficient (refractivity) than the interlayer dielectric 3. The wave guide 8 is able to efficiently transmit the incident light up to the photodiode 2. However, the wave guide 8 also has a problem with reflectivity at an interface between the interlayer dielectric 3 and the wave guide 8 as shown in FIG. 2B. This problem affects light not vertically incident at the bottom of the wave guide 8, especially light reflected from a side wall of the light guide.

### SUMMARY

Embodiments relate to a semiconductor device, and more particularly, to an image sensor and a method for fabricating the same. Embodiments relate to an image sensor capable of, when adopting a wave guide as a transmission path of an incident light, effectively restraining reflection of a side light which is not vertically incident, at a bottom of the wave guide, and a method for fabricating the same.

Embodiments relate to a method for fabricating an image sensor which includes: forming a photodiode over a semiconductor substrate; forming an interlayer dielectric over the semiconductor substrate with the photodiode thereon; forming a trench for a wave guide in an upper part of the interlayer dielectric; forming a refractive layer over a bottom surface of the trench; forming a waveguide dielectric to fill the trench; forming a color filter over the waveguide dielectric; forming an overcoat over the color filter; forming a micro lens over the overcoat.

The interlayer dielectric includes a plurality of metal wires. Forming the dielectric to fill the trench may cover an upper part of the interlayer dielectric to form a protection layer. The trench may be formed by etching a photodiode region of the interlayer dielectric. The waveguide forms a transmission path for incident light. The refractive layer is made of a material having a greater refractivity than the waveguide dielectric. The refractive layer may be made of an organic or inorganic material containing a silicon nitride. Forming the trench may include etching the photodiode region so that a part of the interlayer dielectric is left at a lower part of the trench. The refractive layer may be made of a material having a greater refractivity than the interlayer dielectric being partly left at the lower part of the trench.

In embodiments, an image sensor may include a photodiode formed over a semiconductor substrate. An interlayer dielectric, which may include a plurality of metal wires in a transistor region, may be formed over the semiconductor substrate, including a waveguide dielectric for guiding incident light in a photodiode region. A refractive layer may be formed at a bottom of the waveguide dielectric in the interlayer dielectric. A color filter may be formed over an upper surface of the interlayer dielectric. An overcoat may be formed over the color filter. A micro lens may be formed over the interlayer dielectric. The refractive layer may have a greater refractivity than the wave guide dielectric and the interlayer dielectric. The refractive layer may be made of an inorganic or organic material containing a silicon nitride.

### DRAWINGS

FIG. 1 is a sectional view of a related CMOS image sensor.

FIG. 2A is a sectional view showing a related image sensor equipped with a wave guide, and FIG. 2B is a view showing incident light in the image sensor of FIG. 2A.

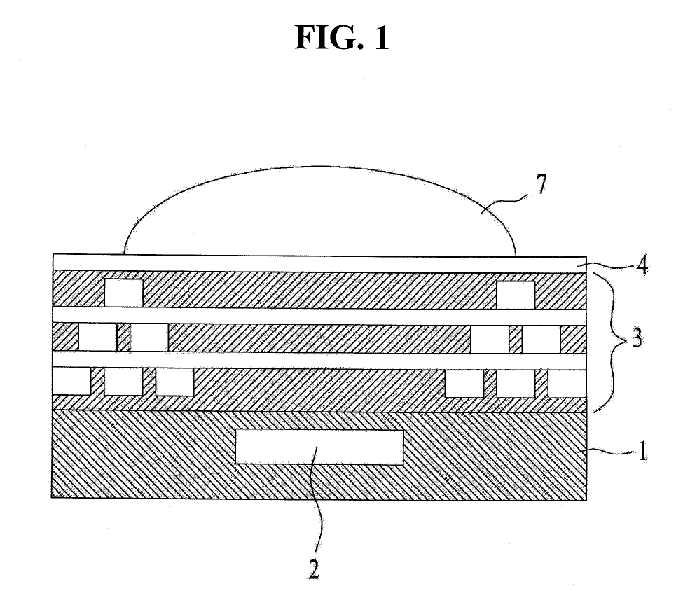

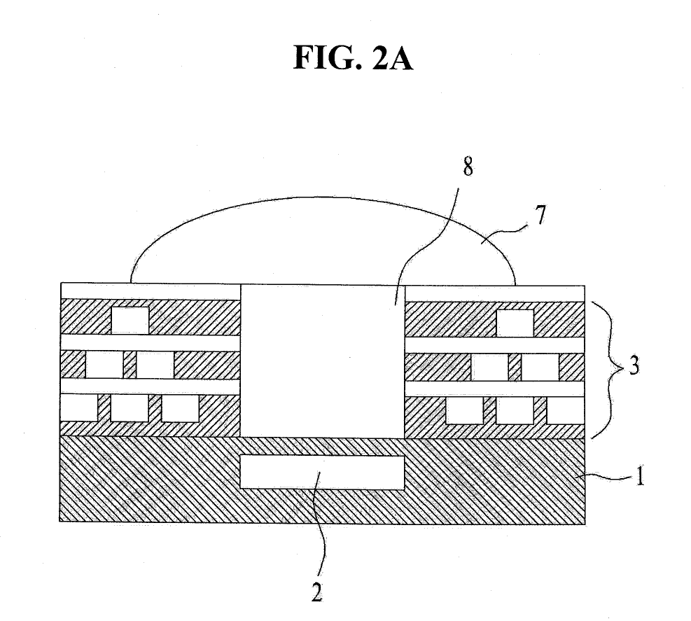

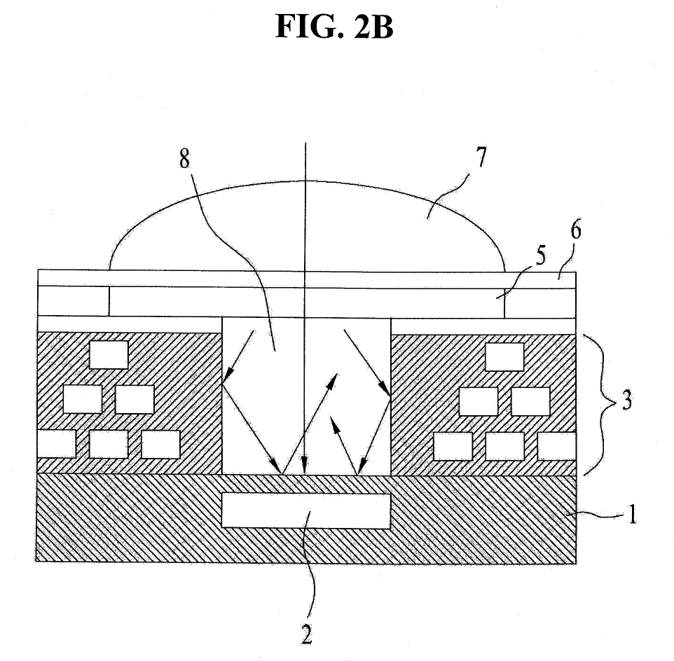

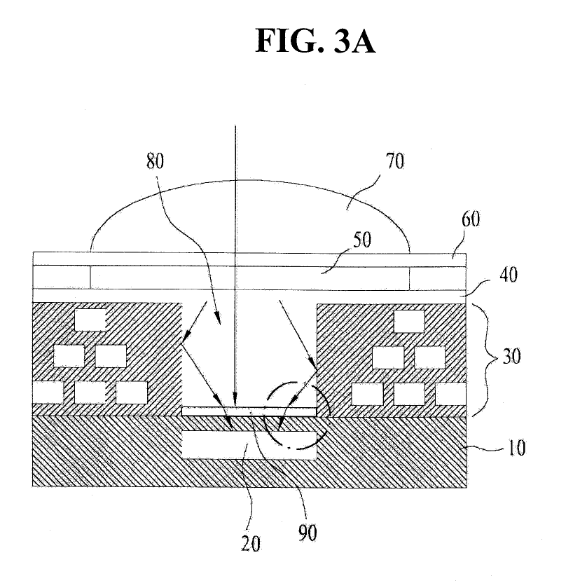

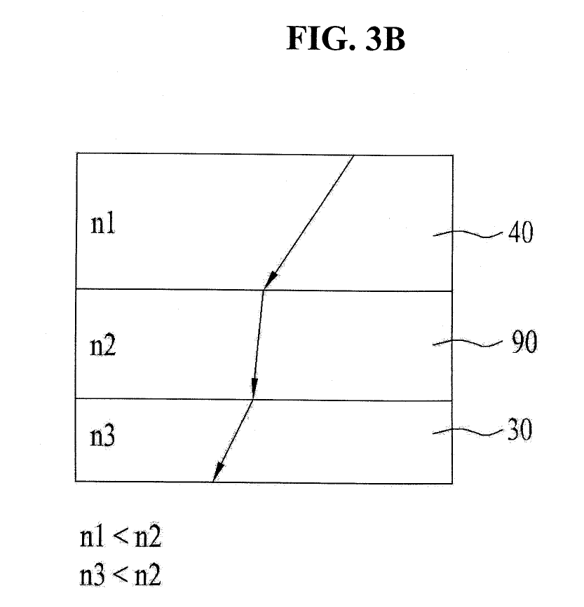

Example FIG. 3A is a sectional view of an image sensor according to embodiments.

Example FIG. 3B is a detailed view showing a layer including a refractive plane in the image sensor of example FIG. 3A.

### DESCRIPTION

Hereinafter, an image sensor and a fabricating method for the same according to embodiments will be described with reference to the accompanying drawings. Example FIG. 3A is a sectional view of an image sensor according to embodiments and example FIG. 3B is a detailed view showing a layer including a refractive plane in the image sensor of example FIG. 3A. Referring to example FIG. 3A, an image sensor according to embodiments is a CMOS image sensor equipped with a wave guide which serves as a transmission path for incident light.

More specifically, the CMOS image sensor may include a photodiode 20, a wave guide dielectric 40, an interlayer dielectric 30 having a multi-layered structure and including the wave guide dielectric 40, a refractive plane or layer 90 having a different refraction coefficient (refractivity) from the wave guide dielectric 40, a color filter 50, an overcoat 60, and a micro lens 70.

The photodiode 20 may be formed over a semiconductor substrate 10. The interlayer dielectric 30 may be formed over the semiconductor substrate 10 in a multi-layered structure. A plurality of metal wires may be included in a transistor region. Additionally, the wave guide dielectric 40 of the wave guide which is the transmission path for the incident light is formed in a photodiode region of the interlayer dielectric 30. In the photodiode region, more particularly, the wave guide dielectric 40 and the color filter 50 disposed above the wave guide dielectric 40 correspond to the transmission path of the incident light from the micro lens 70 to the photodiode 20.

In embodiments, the refractive plane (layer) 90 is formed over a bottom surface of the wave guide dielectric 40. The refractive plane 90 may be made of a material having a greater refraction coefficient than the wave guide dielectric 40 and the interlayer dielectric 30. As a result, reflectivity with respect to light incident from the side, in other words, light not vertically incident, can be reduced at the bottom surface of the wave guide. In other words, reflectivity is reduced at an interface between the dielectric formed at an upper part of the photodiode 20 and the wave guide.

The refractive plane 90 may be made of an inorganic or organic material containing a silicon nitride to have thickness not greater than about 55 nm. As shown in example FIG. 3A, the wave guide dielectric 40 may also function as a protection layer by extending up to and over an upper part of the interlayer dielectric 30. Accordingly, the color filter 50 may be formed over an upper part of the wave guide dielectric 40. However, in embodiments, the color filter 50 may be described as disposed over an uppermost layer of the multilayer interlayer dielectric 30.

The overcoat 60 may be formed over the color filter 50, and the micro lens 70 may be formed over the overcoat 60 corresponding to the color filter 50. According to embodiments, a trench 80 for the wave guide, having a size almost the same as a pixel and a depth corresponding to the thickness of the interlayer dielectric 30, may be formed in the upper part of the photodiode 20 by etching. Otherwise, the trench 80 may be formed by etching to a depth less than the thickness of the interlayer dielectric 30. In the latter case, part of the interlayer dielectric 30 may be left at a lower part of the wave guide dielectric 40.

As shown in example FIG. 3B, the refractive plane 90 has a greater refraction coefficient (refractivity) than the wave guide dielectric 40 and also a greater refraction coefficient than the dielectric formed at the lower part thereof. Therefore, the incident light can be smoothly transmitted up to the photodiode 20 without being reflected by the bottom surface of the wave guide. As described above, by providing a plane layer with a relatively greater refraction coefficient, the image sensor according to embodiments may be able to reduce the reflectivity at the bottom surface of the wave guide by as much as about 20˜30%.

The above-described image sensor according to embodiments is fabricated in the following processes. First, the photodiode 20 may be formed over the semiconductor substrate 10. Next, the interlayer dielectric 30 of the multi-layered structure including the metal wires may be formed over the semiconductor substrate 10 with the photodiode 20.

Afterward, a trench 80 for the wave guide which provides the transmission path of the incident light may be formed in the upper part of the interlayer dielectric 30 over the photodiode 20 by etching the photodiode region of the interlayer dielectric 30. The trench 80 may have almost the same size as a pixel. Also, the depth of the trench 80 may be almost equal to or less than the thickness of the interlayer dielectric 30.

The refractive plane 90, having a first refractivity, is formed over the bottom surface of the trench 80. Inorganic or organic material which may contain a silicon nitride may be deposited with a thickness not greater than about 55 nm by vapor deposition. The trench 80 with the refractive plane 90 at the bottom is filled with a dielectric material forming the wave guide, having a second refractivity. As necessary, the filling process may also cover the upper part of the interlayer dielectric 30, thereby forming the wave guide dielectric 40.

In the above description, the first refractivity may be greater than the second refractivity, and may be greater than refractivity of the dielectric formed at the upper part of the photodiode 20. Next, the color filter 50 may be formed over the interlayer dielectric 30 or the wave guide dielectric 40 over the photodiode 20. An overcoat 60 may be formed over the color filter 50. Finally, micro lens 70 may be formed over overcoat 60.

According to the image sensor as described above, the incident light passing through the micro lens 70 is refracted by the bottom surface of the wave guide and transmitted directly to the photodiode 20. Consequently, the light focusing efficiency can be enhanced. As apparent from the above description, in accordance with embodiments, high reflectivity of a bottom of a wave guide can be prevented while guaranteeing the reflectivity of lateral sides of the wave guide with respect to side light, that is, light not vertically incident. Accordingly, focusing efficiency of the photodiode of an image sensor according to embodiments can be improved and, accordingly, the whole optical sensitivity of the image sensor can be improved.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. A method comprising:
forming a photodiode over a semiconductor substrate;
forming an interlayer dielectric over the semiconductor substrate with the photodiode thereon;
forming a trench for a wave guide in an upper part of the interlayer dielectric;
forming a refractive layer over a bottom surface of the trench;
forming a waveguide dielectric to fill the trench;
forming a micro lens over the waveguide dielectric.

2. The method of claim 1, comprising forming a color filter over the waveguide dielectric and under the micro lens.

3. The method of claim 2, comprising forming an overcoat over the color filter and under the micro lens.

4. The method of claim 1, wherein the interlayer dielectric includes a plurality of metal wires.

5. The method of claim 1, wherein forming the dielectric to fill the trench covers an upper part of the interlayer dielectric.

6. The method of claim 1, wherein the trench is formed by etching a photodiode region of the interlayer dielectric.

7. The method of claim 1, wherein the waveguide forms a transmission path for incident light.

8. The method of claim 1, wherein the refractive layer is made of a material having a greater refractivity than the waveguide dielectric.

9. The method of claim 1, wherein the refractive layer is made of an inorganic material containing a silicon nitride.

10. The method of claim 1, wherein the refractive layer is made of an organic material containing a silicon nitride.

11. The method of claim 1, wherein forming the trench comprises etching the photodiode region so that a part of the interlayer dielectric is left at a lower part of the trench.

12. The method of claim 11, wherein the refractive layer is made of a material having a greater refractivity than the interlayer dielectric being partly left at the lower part of the trench.

13. An apparatus comprising:
a photodiode formed over a semiconductor substrate;
an interlayer dielectric formed over the semiconductor substrate, including a waveguide dielectric for guiding incident light in a photodiode region;
a refractive layer formed at a bottom of the waveguide dielectric in the interlayer dielectric; and
a micro lens formed over the interlayer dielectric.

14. The apparatus of claim 13, wherein the interlayer dielectric comprises a plurality of metal wires in a transistor region.

15. The apparatus of claim 13, comprising a color filter formed over an upper surface of the interlayer dielectric, and under the micro lens.

16. The apparatus of claim 15, comprising an overcoat formed over the color filter and under the micro lens.

17. The apparatus of claim 13, wherein the refractive layer has a greater refractivity than the wave guide dielectric.

18. The apparatus of claim 13, wherein the refractive layer has a greater refractivity than the interlayer dielectric.

19. The apparatus of claim 13, wherein the refractive layer is made of an inorganic material containing a silicon nitride.

20. The apparatus of claim 13, wherein the refractive layer is made of an organic material containing a silicon nitride.
